(19) United States
(12) Patent Application Publication
(10) Pub. No.: US 2026/0220326 A1
(43) Pub. Date: Jul. 30, 2026

(54) METHOD FOR PREDICTING FAILURES OF POWER PLANT EQUIPMENT USING ANOMALOUS SIGNAL PROCESSING AND MACHINE LEARNING BASED ON ACCUMULATED ANOMALY THRESHOLD

(71) Applicant: KOREA ELECTRIC POWER CORPORATION, Naju-si (KR)

(72) Inventors: Jong-Duk SON, Daejeon (KR); Hee-Soo KIM, Daejeon (KR); Yong-Hee JANG, Daejeon (KR)

(21) Appl. No.: 19/144,449

(22) PCT Filed: Jul. 14, 2023
(86) PCT No.: PCT/KR2023/010127

§ 371 Date: Jun. 27, 2025

(30) Foreign Application Priority Data
Apr. 25, 2023 (KR) 10-2023-0054241

(51) Int. Cl. G06F 30/20

(52) U.S. Cl. CPC G06F 30/20

(57) ABSTRACT

The present invention relates to a method for processing anomalies occurring in a power plant facility and, more specifically, to a method for predicting failures of power plant equipment using anomalous signal processing and machine learning based on accumulated anomaly threshold and a method for predicting machine learning according to the same, which can improve the prediction performance of machine learning through a signal processing technique having excellent quality when inputting operation data of a power plant facility by establishing basic learning reference data by managing a cumulative history of anomalies in order to apply a signal processing and data-based machine learning technique for detecting anomalies in advance.

### CROSS REFERENCE TO RELATED APPLICATIONS

This application claims the benefit under 35 U.S.C. section 371, of PCT International Application No. PCT/KR 2023/010127, filed on Jul. 14, 2023, which claims foreign priority to Korean Patent Application No. 10-2023-0054241, filed on Apr. 25, 2023, in the Korean Intellectual Property Office, both of which are hereby incorporated by reference in their entireties.

### TECHNICAL FIELD

### Technical Field

The present invention relates to a method for processing data of anomalies occurring in a power plant facility, and more particularly, to a method for predicting failures of power plant equipment using anomalous signal processing and machine learning based on accumulated anomaly threshold which is to improve the prediction performance of machine learning through a signal processing technique having excellent quality when operating data of a power plant facility is input by establishing basic learning reference data by managing the accumulated history of anomalies in order to apply a signal processing and data-based machine learning technique for detecting anomalies of a failure in advance.

### Background of the Invention

In general, a power plant is a place with a motor that generates electricity and facilities attached to it, and a power plant converts mechanical or thermal energy into electrical energy.

Therefore, energy is required for power generation, and such an energy source is called a power generation source or a power source.

Although water power and thermal power are the main types of power generation, nuclear power generation is gradually increasing in recent years due to rapid increase in power demand and resource problems.

Basically, a power plant is a large plant in which various electric facilities such as fuel transport, air suction fans, cooling pumps, steam turbines, and generators are intricately connected and operated, and various protection systems, control systems, and monitoring systems for stably operating such power generation facilities are provided to detect, monitor, and control all situations generated in the power plant.

In general, as shown in FIG. 1, the amount of detection data generated every second in a power plant generates about 35,000 detection data every second, and the detection signal of the temperature sensor of the boiler is about 2,116.

In order for such facilities to operate stably without failure, it is important to manage anomalies that cause failure during operation, and the existing signal processing method applies a data erasing method according to anomalies that removes all outliers of operation data when outliers occur, so that even when a failure pattern of a facility occurs, it is cumbersome for a user to directly select an arbitrary section and add data.

Moreover, since the history management of anomalies is not performed in the conventional method, it is not possible to manage the history of the amount of data required for learning, so the same work must be repeated even during re-learning, and an appropriate learning section cannot be found. For this reason, when the learning section is selected by the conventional method, the signal pattern in the current state is not learned, resulting in an error in machine learning, and a decrease in the predictive performance of anomalies of failure.

In addition, in the case of a large-capacity facility such as a power generation facility, a large number of sensors are attached to the facility, so that a normal signal and a noise signal are mixed, and since the operation state of the facility changes and the pattern of the signal is frequently changed as the periodic planned preventive maintenance is performed, there has been a recognition that signal preprocessing automation through a quantitative evaluation technique is necessary.

### DETAILED DESCRIPTION OF THE INVENTION

### Object of the Invention

An object of the present invention for solving the above-described problems is to provide a method for processing anomalies generated in a power plant facility. In particular, by applying signal processing and machine learning based on anomalous signal accumulation threshold, to detect anomalies of an equipment failure in advance. The present invention manages the cumulative history of anomalies to establish basic learning reference data, thereby enhancing the predictive performance of machine learning through high-quality signal processing techniques when operational data from power plant equipment is input, based on cumulative threshold values for anomalies.

### Means for Solving the Problem

According to an aspect of the present invention, there is provided a method for predicting failures of power plant equipment using anomalous signal processing and machine learning based on accumulated anomaly threshold, the method including: setting an accumulated threshold of a corresponding anomalous point when an outlier is generated for each inspection item related to operation of a power plant; sequentially acquiring boiler state measurement data measured by a sensor from the power plant, fuel property data, and detection data including power plant operation data over a predetermined time period; calculating whether an outlier is generated for each of the data through each detection data; generating historical data by arranging a date and time when the outlier is generated based on each detection data; and determining the outlier as noise when the accumulated threshold of the anomalous point is not exceeded based on the generated historical data.

The method for a method for predicting failures of power plant equipment using anomalous signal processing and machine learning based on accumulated anomaly threshold according to the present invention for achieving the above-described object further includes selectively removing operation data at a point in time determined as noise because it does not exceed the accumulated threshold of the preset anomaly. Another additional feature of the method for predicting anomalous signal processing and machine learning based on anomalous signal accumulation threshold according to the present invention for achieving the above-described object is that the step of calculating whether an anomalous point occurs for each data is to calculate an anomalous point for each detection data by using a standard deviation or an average.

In order to achieve the above-described object, another additional feature of the method for a method for predicting failures of power plant equipment using anomalous signal processing and machine learning based on accumulated anomaly threshold according to the present invention is that the detection data utilizes data obtained through at least one of the following: a temperature sensor, a vibration sensor, or a pressure sensor.

Another aspect of the a method for predicting failures of power plant equipment using anomalous signal processing and machine learning based on accumulated anomaly threshold according to the present invention for achieving the above-described object is that the accumulated threshold of the anomaly signal is variably set according to the number of sensors utilized in a facility to be applied. Another aspect of the method for predicting anomalous signal processing and machine learning based on anomalous signal accumulation threshold according to the present invention for achieving the above-described object includes: setting an accumulated threshold of a corresponding anomaly when an anomalous point occurs for each inspection item related to operation of a power plant; securing past operation data of a predetermined period of a corresponding power plant or another power plant of the same class, and acquiring detection data including boiler state measurement data measured by a sensor, fuel property data, and power plant operation data from the corresponding operation data; calculating whether an anomalous point occurs in each data based on each detection data; and calculating a date and time when the occurrence of the anomalous point does not exceed the accumulated threshold set based on the generated detection data.

In order to achieve the above-described object, the a method for predicting failures of power plant equipment using anomalous signal processing and machine learning based on accumulated anomaly threshold according to the present invention further includes selectively removing operation data at a time point determined as noise because it does not exceed a preset accumulation threshold of anomalies.

In another aspect of the present invention, a method is provided for predicting failures of power plant equipment using anomalous signal processing and machine learning based on accumulated anomaly threshold, wherein the calculating of whether an anomaly point occurs for each data includes calculating an anomaly point for each detection data using a standard deviation or an average. In order to achieve the above-described objects, according to another aspect of the present invention, a method is provided for predicting anomalous signal processing and machine learning based on anomalous signal accumulation threshold, wherein the detection data may be obtained through at least one of the following: a temperature sensor, a vibration sensor, or a pressure sensor.

In order to achieve the above-described object, another additional feature of the a method for predicting failures of power plant equipment using anomalous signal processing and machine learning based on accumulated anomaly threshold according to the present invention is that the accumulation threshold of the anomalous point is variably set according to the number of sensors used in the applied facility.

According to an aspect of the present invention, there is provided a machine learning prediction method according to anomalous sign-based signal processing according to anomalous sign accumulation threshold, the method including: setting an accumulation threshold of a corresponding anomalous point when an outlier point occurs in each inspection item related to operation of a power plant; acquiring source data for deep learning for each inspection item related to operation of the power plant; calculating whether an anomalous point occurs in each of the data through each inspection data included in the acquired source data;

generating history data by arranging a date and time when the anomalous point occurs based on each of the inspection data; determining the outlier as noise when the accumulated threshold of the anomalous point is not exceeded based on the generated history data; and implementing a prediction model for suppressing the occurrence of the anomalous point by performing deep learning based on driving data exceeding the accumulation threshold of the anomalous point set based on the generated history data.

In order to achieve the above-described object, the machine learning prediction method according to anomalous sign-based signal processing according to anomalous sign accumulation threshold according to the present invention further includes a step of predicting in real time the anomalous point occurrence sign according to the operation of the power plant based on the prediction model.

In order to achieve the above-described objects, the present invention provides a machine learning prediction method according to anomalous sign-based signal processing according to an anomalous sign accumulation threshold, the acquiring of the source data may include selecting and applying any one of the steps of: sequentially acquiring, over a predetermined time period, measurement data including boiler state measurement data measured by a sensor from a power plant, fuel property data, and power plant operation data; acquiring past operation data for a predetermined period of a corresponding power plant or another power plant of the same class, and acquiring, in the corresponding operation data, boiler state measurement data measured by a sensor, fuel property data, and measurement data including power plant operation data at an instant time, which are measured by the sensor.

### Effects of the Invention

According to the present invention, provided are the a method for predicting failures of power plant equipment using anomalous signal processing and machine learning based on accumulated anomaly threshold according to the same, and the method for predicting machine learning according to the same, the accuracy of a machine learning prediction model and the prevention of failure and operation reliability of power generation equipment can be improved by quantifying the correlation of the anomalous point signals of a power plant, and an accurate time point of failure can be determined while monitoring the equipment, thereby establishing a strategy for condition-based maintenance or a preliminary measurement ratio of power plant equipment.

### BRIEF DESCRIPTION OF DRAWINGS

FIG. 1 is an exemplary diagram schematically illustrating an amount of settlement data detected in a general thermal power plant.

FIG. 2 is a flow exemplary diagram for explaining an anomaly-based signal processing and machine learning prediction process according to an anomaly accumulation threshold according to the present invention.

FIG. 3 to FIG. 10 are exemplary views in which the anomaly-based signal processing and machine learning prediction method according to the accumulated anomaly threshold according to the present invention are applied.

### MODE OF THE INVENTION

Hereinafter, a method for predicting failures of power plant equipment using anomalous signal processing and machine learning based on accumulated anomaly threshold according thereto according to the present invention will be described with reference to the accompanying drawings.

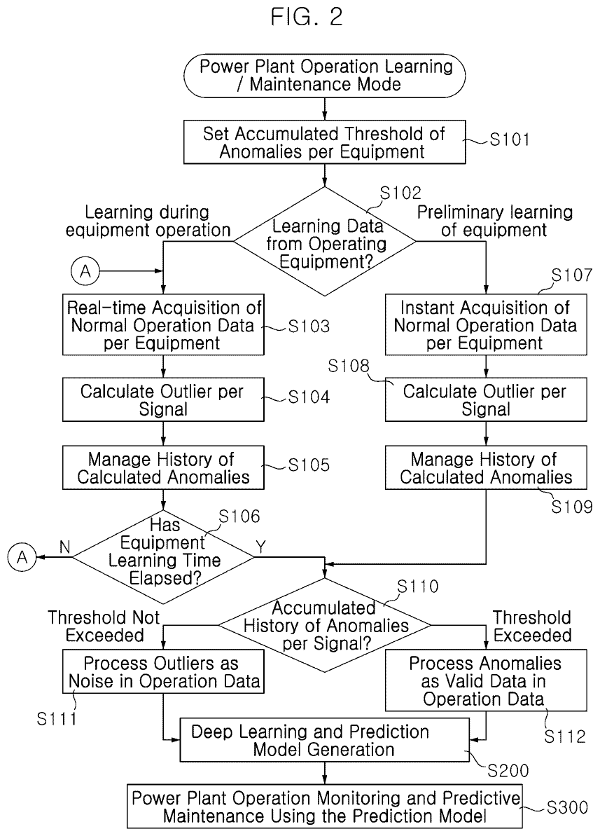

FIG. 2 is a flow exemplary diagram for explaining the anomaly-based signal processing and machine learning prediction process according to the anomaly accumulation threshold according to the present invention, and when an anomalous point occurs for each of the inspection items related to the operation of the power plant in step S101, the accumulation threshold of the corresponding anomalous point is set.

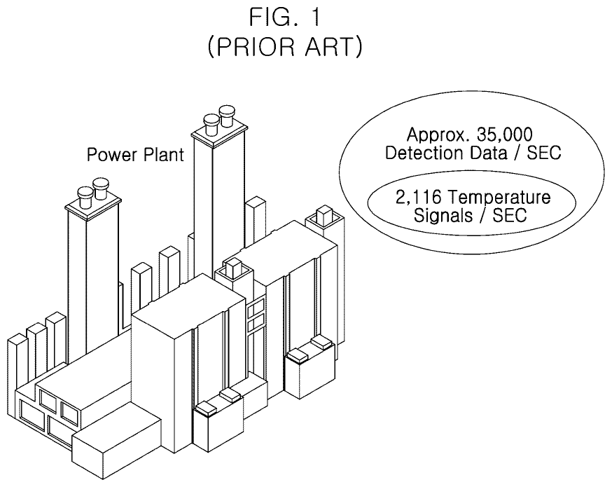

That is, as illustrated in FIG. 1, the power plant generates about 35,000 detection data every second, and the detection data is mixed with normal power plant operation data, abnormal anomalies, and noise.

Accordingly, all of about 35,000 detection data may be viewed as monitoring targets, and accordingly, the checklist for setting the cumulative threshold in the process of step S101 may set all of up to 35,000.

However, in practice, since the inspection item to be preferentially managed in the power plant is the boiler, the state detection data of 2,116 boilers will be described as the target in the process of describing the embodiment of the present invention.

In addition, since the state detection data generated in the boiler is usually detected through a temperature sensor, a vibration sensor, a pressure sensor, and the like, the data detected by each sensor should be processed separately.

Assuming that the cumulative threshold is set to 3 to 5 in the process of step S101, the facility manager selects the type of data for generating the machine learning prediction model in the process of step S102.

At this time, in the process of step S102, there are two main perspectives in which the equipment manager selects the type of data for generating the machine learning prediction model, and even if it takes time, the equipment manager accumulates the data of the currently operating power plant facility to generate the prediction model optimized for the corresponding power plant, or borrows the accumulated data of other dome-class power plants to generate the prediction model in a short time.

The two perspectives described above are the difference between whether to generate an optimized prediction model even if it takes time or whether to shorten the time because it is an optimized prediction model.

As a compromise, there may be a method of borrowing past operation data of the currently operating power plant, but this also does not take into account the impact of the aging of the facility, so it will not be possible to obtain an optimized prediction model at this point.

Therefore, when the facility manager determines to accumulate data of the currently operating power plant facility in order to generate an optimized prediction model in the process of step S102, the process proceeds to step S103 and acquires the boiler state measurement data measured by the sensor from the currently operating power plant in real time.

Whether there is an anomaly in each of the detection data acquired in step S103 is calculated by calculating whether an anomaly exists in each of the data through step S104, and in this case, the process of calculating the anomaly uses data statistical data such as an average value or a standard deviation.

When an anomaly is calculated through the process of step S104, historical data is generated by organizing the date and time when the anomaly occurs based on each detection data in the process of step S105.

After that, in step S106, it is checked whether the training time for facility operation has elapsed, which is preferably set together when the facility manage r decides to accumulate data of the power plant facility currently operating in order to generate an optimized prediction model in step S102.

Therefore, if it is determined that the training time for facility operation has not elapsed in the process of step S106, the process proceeds to step S103 and the above-described process is repeatedly performed.

On the other hand, if it is determined that the learning time for facility operation has elapsed in the process of step S106, the process proceeds to step S110.

Prior to describing the process of step S110, if the facility manager determines to generate the prediction model in a short period of time in the process of step S102, past operation data for a certain period of the corresponding power plant or other power plant of the same class is obtained in the process of step S107, and boiler state measurement data measured by sensors are obtained from the corresponding operation data in an instant.

Thereafter, in step S108, whether or not an anomaly has occurred in each of the data is calculated through the detection data obtained in step S107, and the date and time when the anomaly has occurred are summarized based on each of the detection data through step S109 to generate historical data, and then the process proceeds to step S110.

Therefore, in step S110, it is determined whether the accumulated threshold of the set anomaly is exceeded based on the history data generated through the process of step S105 or step S109.

At this time, assuming that the accumulated threshold is set to 3 in the process of step S101, when the accumulated value of the anomalies in the history data generated through the process of step S105 or step S109 is 3 or less, it is determined as noise rather than a substantial anomaly, and the process proceeds to step S111.

On the other hand, when there is data in which the accumulated value of anomalies exceeds 3 in the history data generated through the process of step S105 or step S109 in step S110, the corresponding operation data is recognized as data having a substantial abnormality, and the process proceeds to step S112.

Therefore, all of the data from which the anomaly is deleted in step S111 or the data maintaining the anomaly in step S112 are used as the source of the deep learning and prediction model generation mode in step S200.

Through this, deep learning is performed based on historical data having substantially anomalies in the step S200 process, and a predictive model including the cause of the anomalies, improvement directions, and operation indicators is generated in the trained process.

As described above, by using the prediction model generated through the step S200 process, it is possible to perform operation monitoring and preventive maintenance of the power plant in step S300.

Looking at the case of applying the anomaly-based signal processing and machine learning prediction method according to the accumulated anomaly threshold according to the present invention as described above, the cumulative anomalous point-based machine learning prediction result was evaluated using the operation data (temperature signal) for the boiler of the domestic 870MW-class thermal power plant.

At this time, 2, 116 temperature signals were applied to the boiler during the period from January 2019 to February 2020 (14 months), and anomaly cumulative value signal processing and machine learning model construction and evaluation were performed.

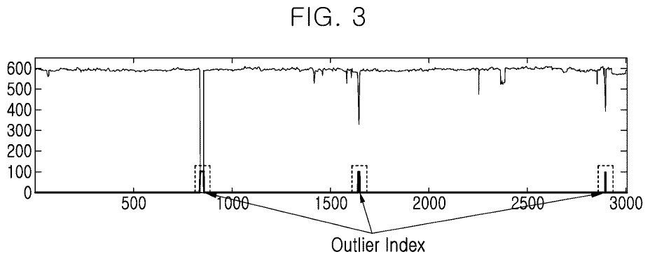

In addition, anomalies are found in the temperature signal of each boiler tube by various methods (mean, standard deviation, etc.), and an index for the anomalies is displayed as shown in FIG. 3.

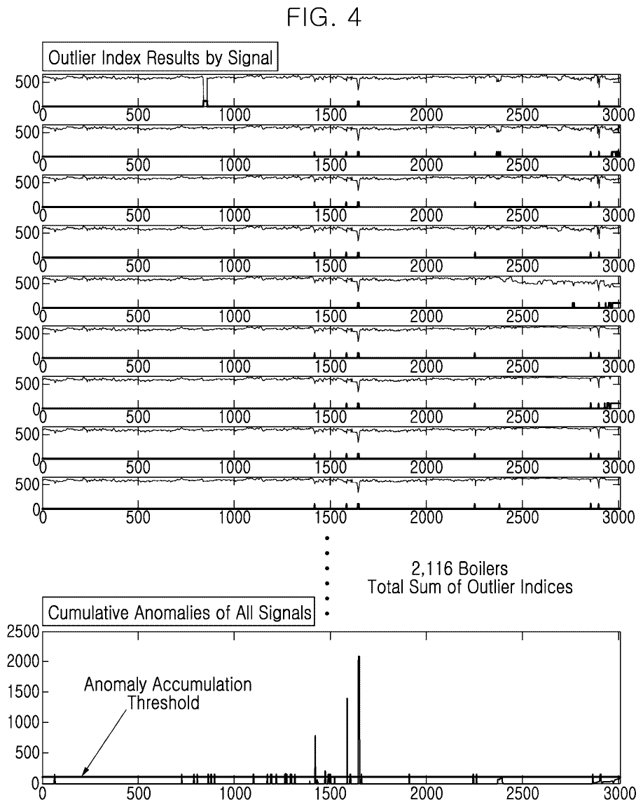

In this case, it may be confirmed that the anomaly for the entire period for each date and time of the 2,116 temperature signals of the boiler is shown for each signal, and the cumulative reference value set by the user in the accumulated anomaly value of the entire signal within the evaluation period may be confirmed as shown in FIG. 4.

Hereinafter, for the formation of the comparison group, it will be examined from two perspectives.

The first comparison group is to generate a learning model after erasing all anomalies as in the previous method.

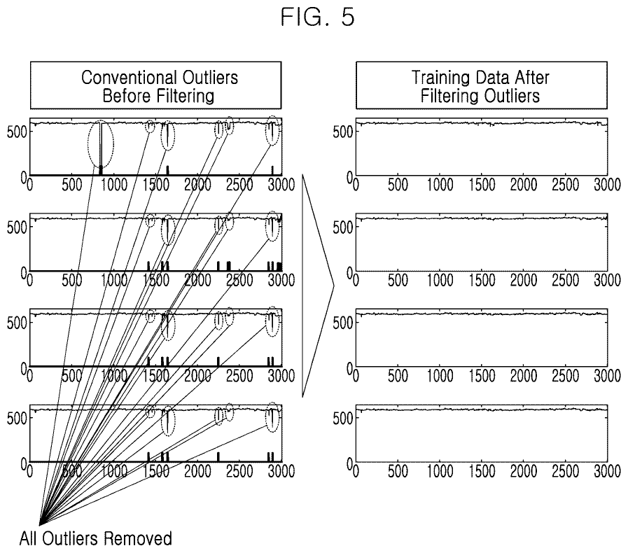

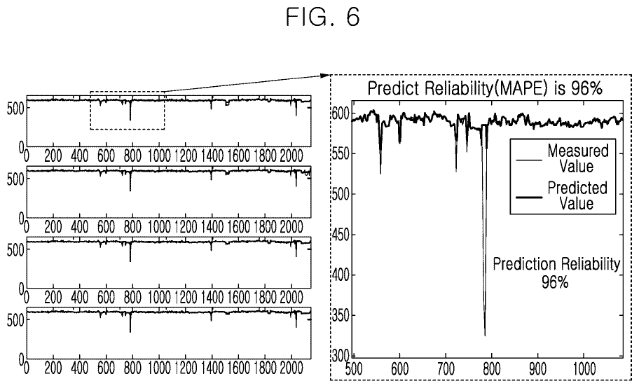

That is, when all the existing anomalies are removed to generate machine learning training data (see FIG. 5), and a learning model is constructed and tested, the predicted reliability of machine learning is 96% as shown in FIG. 6.

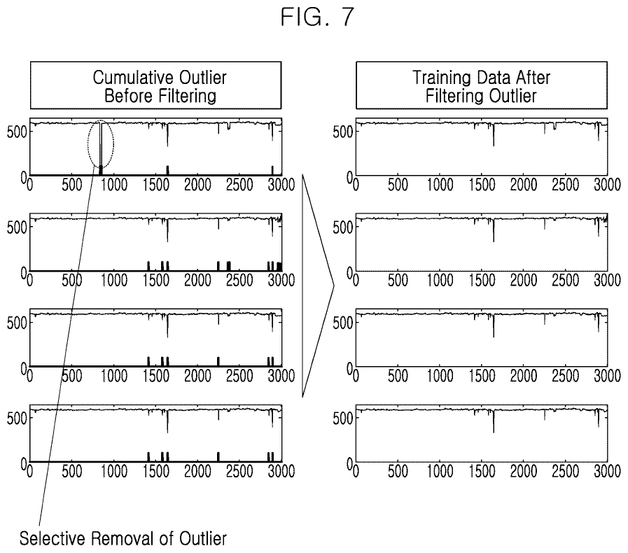

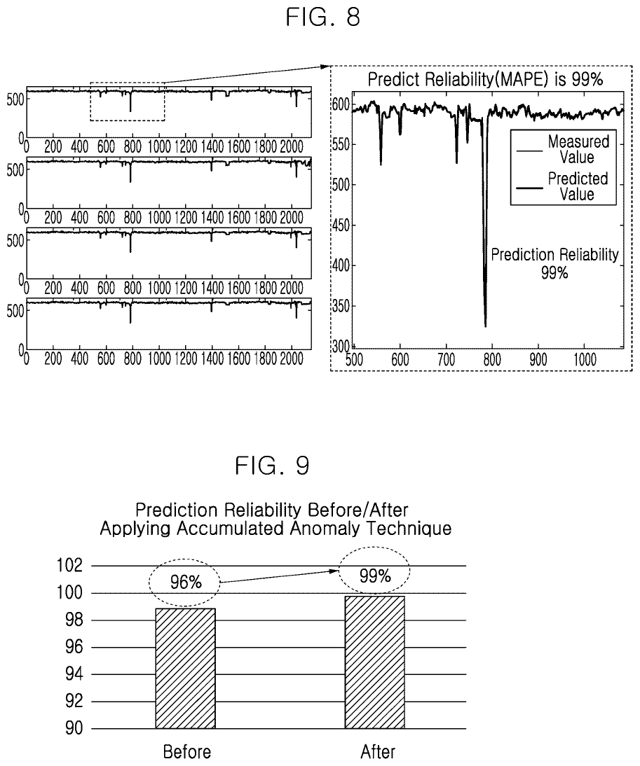

In the second comparative group, when an anomaly threshold accumulation value is set according to the method according to the present invention, an anomaly having an accumulation value of 3 or less determined as noise is erased, and an anomaly having an accumulation value of 3 or more determined as an actual anomaly is left and filtered, training data for building a learning model is summarized as shown in FIG. 7, and machine learning prediction reliability is 99% as shown in FIG. 8.

Therefore, the signal processing and machine learning evaluation were performed using the temperature data for boilers in domestic 870MW-class thermal power plants by applying the cumulative anomaly technique as boiler temperature data for the period from January to December 2019 to generate machine learning training data. In addition, the prediction test of the machine learning model was performed on the data for the period from January to February 2020.

Accordingly, the performance of the machine learning prediction model was compared with the case where all anomalies were removed as in the existing method and the case where anomalies were selectively removed by the method according to the present invention.

The reliability of the predictive performance of the machine learning model has improved from 96% to 99%, which is believed to have improved the performance of the learning model by selectively removing anomalies caused by sensor noise and communication errors. (See FIG. 9)

In addition, it was confirmed that filtering through the accumulated anomalies becomes an effective method for determining the normal signal for the corresponding facility signal.

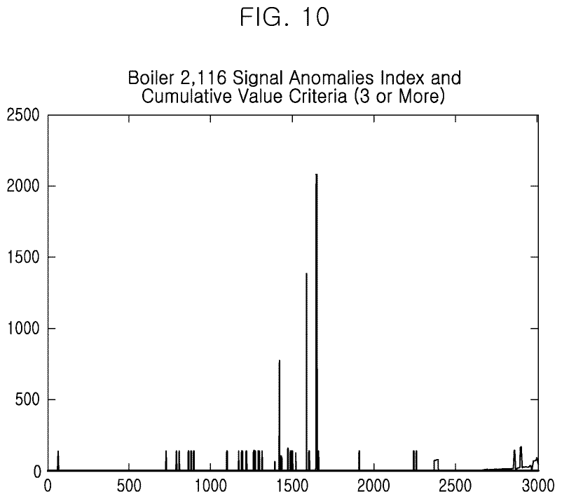

It was confirmed that the fact that the signals according to the operation of the facility move based on correlation can be used as an index to filter the normal operation signal through the cumulative index technique. (See FIG. 10)

Although the exemplary embodiments of the present invention have been illustrated and described above, the present invention is not limited to the specific embodiments described above, and various modifications can be made by a person having ordinary skill in the art to which the method belongs without departing from the gist of the present invention claimed in the claims, and such modifications should not be individually understood from the technical spirit or the prospect of the present invention.

1. A method for predicting failures of power plant equipment using anomalous signal processing and machine learning based on accumulated anomaly threshold, the method comprising:
setting an accumulation threshold of an anomaly occurrence when an anomaly occurs in each of a plurality of checks related to operation of a power plant;
sequentially acquiring detection data measured by a sensor from the power plant over a predetermined time period;
calculating whether the anomaly occurrence occurs from the detection data;
generating history data by arranging the date and time when the anomaly occurs; and
determining the data as noise when the date and time do not exceed the accumulation threshold of the anomaly occurrence set based on the generated history data.

2. The method of claim 1, further comprising selectively removing the driving data at the time point determined as the noise.

3. The method of claim 1, wherein the step of calculating whether the anomaly occurs for each data comprises calculating the anomaly for each detection data using a standard deviation or an average.

4. The method of claim 1, wherein the detection data is at least one of boiler state measurement data, fuel property data, and power plant operation data.

5. The method of claim 1, wherein the detection data utilizes data obtained through at least one of the following: a temperature sensor, a vibration sensor, or a pressure sensor.

6. The method of claim 1, wherein the accumulated threshold of the anomaly is variably set according to the number of applied facilities and sensors to be utilized.

7. A method for predicting failures of power plant equipment using anomalous signal processing and machine learning based on accumulated anomaly threshold, the method comprising:
setting an accumulation threshold of an anomaly when an anomaly occurs for each of a plurality of checks related to operation of a power plant;
acquiring past operation data for a predetermined period of time;
acquiring detection data including at least one of the following: boiler state measurement data, fuel property data and power plant operation data measured by a sensor from the operation data;
calculating whether an anomaly occurs for each of the acquired detection data;
generating history data by arranging the date and time when the anomaly occurs; and
determining the data as noise when the accumulation threshold of the anomaly does not exceed the accumulation threshold of the anomaly set based on the generated history data.

8. The method of claim 7, further comprising selectively removing the operation data at the time point determined as the noise because the accumulated threshold of the preset anomaly is not exceeded.

9. The method of claim 7, wherein the calculating of whether the anomaly occurs for each data comprises calculating an anomaly for each detection data using a standard deviation or an average.

10. The method of claim 7, wherein the detection data utilizes data obtained through at least one of the following: a temperature sensor, a vibration sensor, or a pressure sensor.

11. The method of claim 7, wherein the accumulated threshold of the anomaly is variably set according to the number of applied facilities and sensors used.

12. A machine learning prediction method according to anomalous sign-based signal processing with anomalous sign accumulation threshold, the method comprising:
setting an accumulation threshold of the anomalies when the anomalies occur for each inspection related to operation of a power plant;
obtaining source data for deep learning for each inspection related to operation of the power plant;
calculating whether the anomalies occur through each inspection data included in the obtained source data;
generating history data by arranging a date and time when the anomalies occur based on the inspection data;
determining the data as noise when the data do not exceed the accumulation threshold of the anomalies set based on the generated history data; and
implementing a prediction model for suppressing the occurrence of anomalies by performing deep learning based on operation data exceeding the accumulation threshold of the anomalies set based on the generated history data.

13. The method of claim 12, further comprising predicting in real time an indication of occurrence of an anomaly according to the operation of the power plant based on the prediction model.

14. The method of claim 12, wherein the step of the obtaining of the source data comprises sequentially obtaining detection data including at least one of boiler state measurement data, fuel property data or power plant operation data measured by a sensor from a power plant over a predetermined time period.

15. The method of claim 12, wherein the step of obtaining of the source data comprises: obtaining past operation data of a predetermined period, and obtaining detection data including at least one of boiler state measurement data, fuel property data, and power plant operation data measured by a sensor from the operation data in an instant.
